(19) United States
(12) Patent Application Publication
(10) Pub. No.: US 2002/0083896 A1
(43) Pub. Date: Jul. 4, 2002

(54) Vacuum deposition apparatus

(76) Inventor: Young Ho Bae, Kyoungeangbuk-do (KR)

Correspondence Address: BIRCH STEWART KOLASCH & BIRCH, PO BOX 747, FALLS CHURCH, VA, 22040-0747, US

(21) Appl. No.: 10/029,035

(22) Filed: Dec. 28, 2001

(30) Foreign Application Priority Data
Dec. 28, 2000 (KR) P2000-84714

(51) Int. Cl. C23C 16/00

(52) U.S. Cl. 118/719; 118/724

(57) ABSTRACT

A vacuum deposition apparatus for minimizing the breakage of a glass caused by a slide miss of the glass, which includes a susceptor for applying heat to a glass substrate and generating plasma; a lift pin for supporting the glass substrate; a robot arm for transferring the glass substrate to and returning the glass substrate from the susceptor; a stopper pin for rendering the stable transfer and return of the robot arm; and a groove which is formed at a slide part of the susceptor and into which a film-forming material collects upon a deposition process.

### BACKGROUND OF THE INVENTION

1. Field of the Invention

The present invention relates to a fabricating apparatus of a liquid crystal display, and more particularly to a vacuum deposition apparatus which is suitable for reducing the breakage of a glass caused by the slide miss of the glass.

2. Description of the Related Art

Generally, a liquid crystal display (LCD) device controls the light transmissivity of liquid crystal cells in accordance with video signals for displaying a picture corresponding to the video signals on a liquid crystal panel having the liquid crystal cells arranged in a matrix pattern. To this end, the LCD device includes an active area having the liquid crystal cells arranged in an active matrix type, and driving circuits for driving the liquid crystal cells in the active area. More specifically, the LCD device includes a lower plate in which thin film transistors for switching the liquid crystal cells, driving circuits for driving the thin film transistors and signal lines connected between the driving circuits and the thin film transistors are mounted on a lower substrate; an upper plate having color filters coated on an upper substrate in correspondence with the matrix liquid crystal cells in such a manner to be separated for each cell area by a black matrix stripe, and transparent electrodes coated on the surfaces of the color filters; a spacer provided between the upper plate and the lower plate to assure a certain cell gap; and liquid crystal disposed in a space defined between the upper and lower plates by the spacer. Such a liquid crystal display device is fabricated by preparing the upper plate and the lower plate separately, causing them to adhere to each other and then injecting the liquid crystal through a liquid crystal injection hole provided at the side portion thereof, and thereafter by coating the liquid crystal injection holes with a sealant and then curing the sealant.

In such a fabricating method of a liquid crystal display device, an active layer included in a channel part of a thin film transistor and a protective layer protecting the transistor are generally formed by using a plasma-enhanced chemical vapor deposition (PECVD) process. Such PECVD process is implemented by a vacuum deposition apparatus as shown in FIG. 1 and 2.

Referring to FIG. 1 and 2, a conventional vacuum deposition apparatus includes a process chamber 2, and a susceptor 10 used as a lower electrode for heating a glass substrate 4 in the process chamber 2 and generating plasma.

The glass substrate 4 is transferred onto the susceptor 10 by a robot arm 8, and returned after a deposition process.

The susceptor 10 is fixed to a support plate 18 and positioned at a certain height within the process chamber 2 by a support bar 20 that supports the support plate 18. A lift pin 6 is installed on the susceptor 10 for moving the glass substrate 4 up and down. The susceptor 10 is made to move in a vertical direction by a time belt 14 connected to the support bar 20 and a motor 12 for driving the time belt 14.

The time belt 14 driven by the motor 12 moves the support bar 20 to a desired height to cause the susceptor 10 to move to a corresponding position according to the process. In this case, the susceptor 10 is generally moved to its positions in 4 steps, that is, to the exchange position, to the load position, to the process position and to the spacing position. These positions of the susceptor 10 are determined by the driving time of the time belt 14.

The apparatus includes a location sensor 17 positioned at a side of the support bar 20 for sensing the position of the susceptor 10 and a sensed part 23 moving vertically together with the support bar 20 and positioned in a manner to face the location sensor 17.

The location sensor 17 is installed to be fixed and includes a first sensor 15 and a second sensor 16 that have different heights and thicknesses from each other.

The sensed part 23 includes a first projected part 21 adapted to selectively contact the first sensor 15 in accordance with the position of the susceptor 10 and a second projected part 22 adapted to contact the second sensor 16 at a different location in accordance with the position of the susceptor 10.

The first sensor 15 and the second sensor 16 are normally photo sensors. They generate an ON signal when they contact the first projected part 21 and the second projected part 22 of the sensed part 23. They generate an OFF signal when they do not contact the first projected part 21 and the second projected part 22 of the sensed part 23. Accordingly, the positions of the susceptor 10 can be sensed in the vacuum deposition apparatus.

To describe the motion of the vacuum deposition apparatus with such a composition, the robot arm 8 transfers the preheated glass substrate 4 from a heat chamber not shown to the process chamber 2. After moving to the process chamber 2, the robot arm 8 moves forward in the advancing direction as shown in FIG. 2, to have the glass substrate 4 positioned at the top of the susceptor 10. In this case, the robot arm 8 moves up to a home position by the time belt 14 and is driven for the time to be positioned so as not to interfere with the susceptor 10 and the lift pin 6. In this way, after the glass substrate 4 is positioned at the top of the susceptor 10 by the robot arm 8, the susceptor 10 is moved up to a load position by the time belt 14 that is driven for a set time, so that the glass substrate 4 is supported by the lift pin 6. At this moment, the robot arm 8 is in contact with the glass substrate 4 and the susceptor 10.

On the other hand, the first projected part 21 does not contact the first sensor 15 while the second projected part 22 of the sensed part 23, which moves up with the support bar 20, does contact with the second sensor 16 of the location sensor 17.

Thus, when the susceptor 10 is positioned in the load position, the robot arm 8 comes out of the process chamber. Then the susceptor 10 is moved up to the process position by the time belt 14 that is driven for a set period of time. At the same time, the lift pin 6 supporting the glass substrate 4 is inserted into the inside of the susceptor 10 so that the glass substrate 4 is positioned on the surface of the susceptor 10. At this moment, the ON signal is generated from the first sensor 15 and the second sensor 16 of the sensed part 23 which has moved up with the support bar 20 of the susceptor 10. Subsequently, after moving up to the spacing position as the next position, the susceptor 10 applies heat and voltage to the glass substrate 4 and a desired film is deposited on the glass substrate 4 by gas and plasma.

When the deposition process is completed, the time belt 14 is driven in a reverse direction that is, different from the above described sequence, and the susceptor 10 carries out the foregoing process in a reverse order so that the glass substrate 4 is conveyed to succeeding process equipment by the robot arm 8.

Thus, in the process position among the motions of the conventional vacuum deposition apparatus, the vacuum deposition apparatus, as shown in FIG. 3, includes the process chamber 2, the susceptor 10 on which the glass substrate 4 is safely placed within the process chamber 2, and the lift pin 6 for supporting the glass substrate 4.

The glass substrate 4 is slid by the robot arm 8 and safely placed on the surface of the susceptor 10. At this moment, the susceptor 10 applies heat to the glass substrate 4 and is used as a lower electrode for generating plasma.

The robot arm 8 transfers the pre-heated glass substrate 4 from the heat chamber (not shown) to the process chamber 2. After moving to the process chamber 2, the robot arm 8 moves forward in the advancing direction to position the glass substrate 4 at the top of the susceptor 10. At this moment, the lift pin 6 supporting the glass substrate 4 is inserted into the inside of the susceptor 10 to position the glass substrate 4 at the surface of the susceptor 10.

At this moment, the robot arm 8 puts the glass substrate 4 2˜3 mm before a stopper pin 28 from the end of the glass substrate 4. At this time, it become unstable upon the transfer and the conveyance of the robot arm 8 because the gap of the stopper pin 28 and a slide part where the glass substrate 4 is safely placed, is 5 mm.

Also, the robot arm 8 is inclined at around 85 degree and moves up for safely placing the glass substrate 4 on the surface of the susceptor 10. Due to this fact, upon safely placing the glass substrate 4 on the susceptor 10, it becomes inclined and pressed at one side. Consequently, the friction between the surface of the susceptor 10 and the glass substrate 4 changes whereby the film-forming material collects at the slide part of the susceptor 10.

FIG. 4A to 4D are sectional views taken along the line A-A′ of FIG. 3, and represent the process whereby the glass substrate 4 is damaged by the film-forming material which occurs on the surface of the susceptor 10 due to the frictional difference between the surface of the susceptor 10 and the glass substrate 4 safely placed on the susceptor 10 in an inclined manner.

When the glass substrate 4 is slid into the slide part 41 of the susceptor 10, it is caught by the film-forming material 11 to cause a slide to miss occur. Thereby, there occurs a problem whereby the glass substrate 4 is broken. The possibility of this occurrence increases because a bend of the substrate becomes severe due to the enlargement of the substrate.

Also, there is difficulty in obtaining the material because pyrex, a kind of glass, is used as the material for the susceptor 10.

### SUMMARY OF THE INVENTION

Accordingly, it is an object of the present invention to provide a vacuum deposition apparatus for minimizing the breakage of glass caused by the slide miss of the glass.

In order to achieve these and other objects of the invention, a vacuum deposition apparatus according to one aspect of the present invention includes a susceptor for applying heat to a glass substrate and generating plasma; a lift pin supporting said glass substrate; a robot arm transferring said glass substrate to and returning said glass substrate from said susceptor; a stopper pin which provides for the stable transfer and return of said robot arm; and a groove which is formed at a slide part of said susceptor and into which a film-forming material provided in the deposition process is inserted.

In the apparatus, the gap between said slide part and the stopper pin is at least 3 mm. In the apparatus, the gap is 10 mm. In the apparatus, the material of the susceptor is quartz. In the apparatus, the section of the groove formed in the slide part has the shape of a polygon. In the apparatus, the bottom face of the groove formed in the slide part has a curved shape. In the apparatus, the bottom face of the groove formed in the slide part includes an incline plane and a perpendicular plane.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

These and other objects of the invention will be apparent from the following detailed description of the embodiments of the present invention with reference to the accompanying drawings, in which:

FIGS. 1 and 2 are respectively a sectional view and a plan view representing a conventional vacuum deposition apparatus;

FIG. 3 is a plan view representing the gap between a stopper pin and a safe-placed part of a glass substrate shown in FIG. 2;

FIGS. 4A to 4D are sectional view representing in steps that a film-forming material occurs when a glass substrate is slid into a susceptor;

FIG. 5 is a plan view representing the vacuum deposition apparatus according to the present invention;

FIG. 6 is a sectional view taken along the line B-B′ of FIG. 5;

FIGS. 7 to 9 are sectional views of a groove formed in the slide part of a susceptor; and

FIGS. 10A to 10C are sectional views showing that film-forming material collects in the groove when the glass substrate is slid into a susceptor.

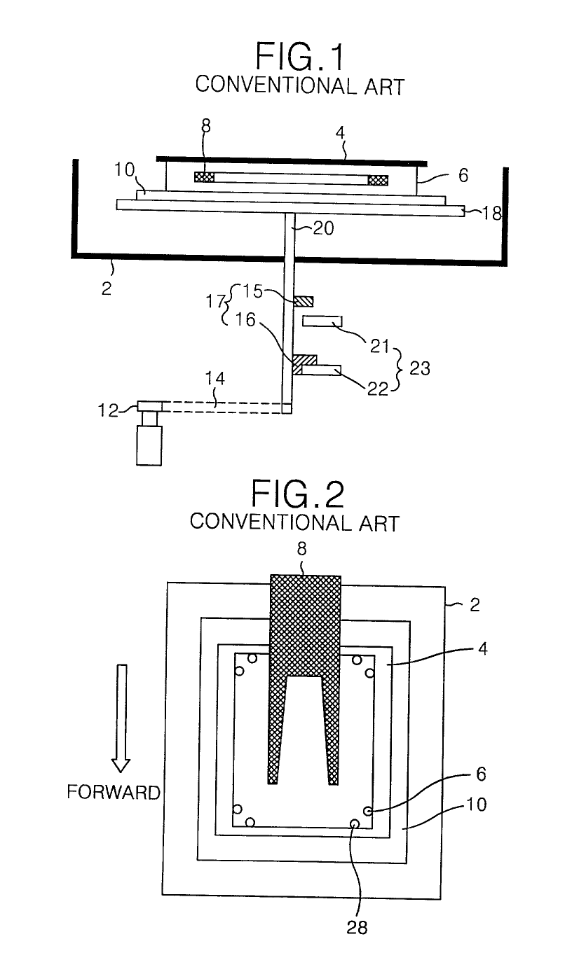

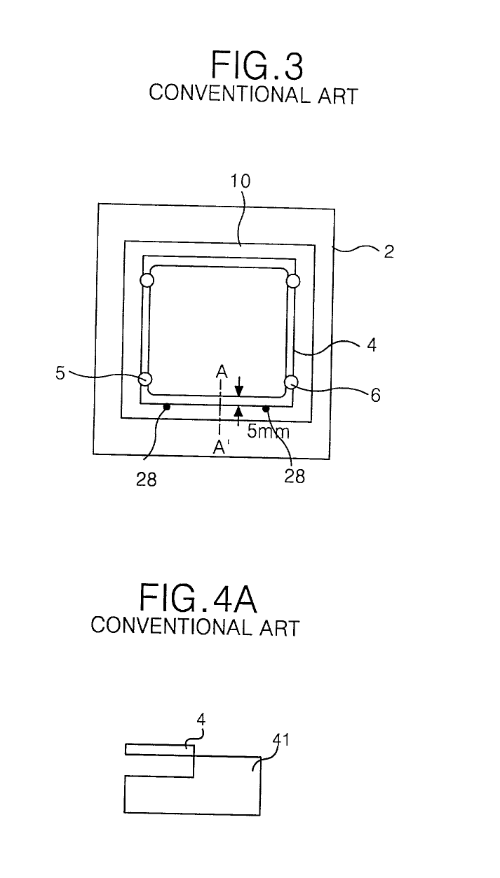

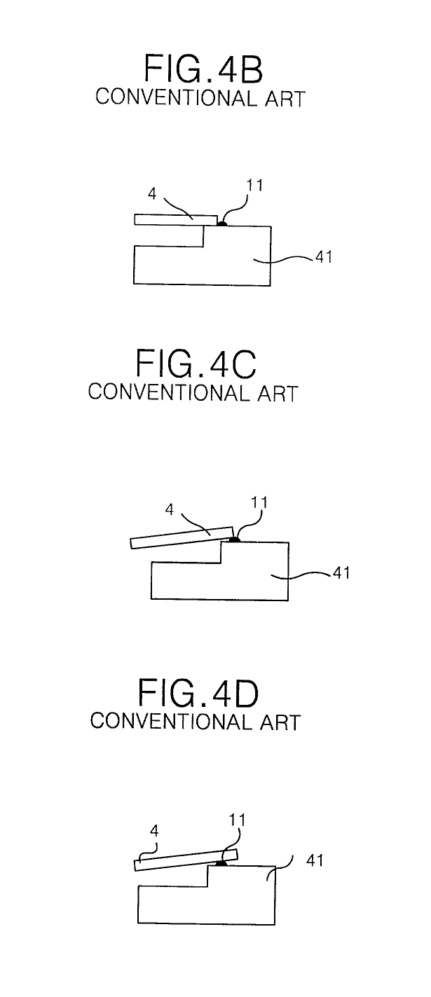

### DETAILED DESCRIPTION OF THE PREFERRED EMBODIMENT

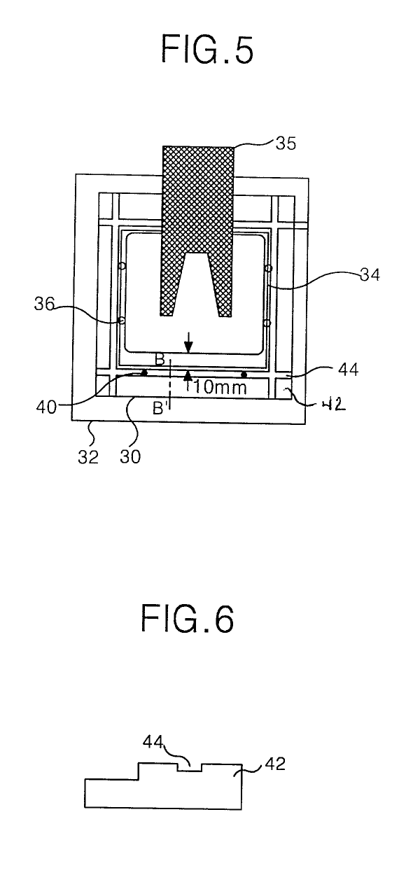

With reference to FIG. 5 to 10c, the preferred embodiment of the present invention is explained as follows:

Referring to FIG. 5, the vacuum deposition apparatus according to the present invention includes a susceptor 30 for applying heat to a glass substrate 34 safely placed within a process chamber and generating plasma, a lift pin 36 supporting the glass substrate 34, a robot arm 35 for transferring the glass substrate 34 to and returning from the susceptor 30, and a stopper pin 36 for the stabilization of the transfer and the return of the robot arm 35.

The glass substrate 34 is transferred into the process chamber 32 by the robot arm 35 and safely placed on the surface of the susceptor 30. The susceptor 30 is used as a lower electrode for applying heat to the glass substrate 34 and generating plasma. Quartz is used as the material of the susceptor 30 for the ease of supply. The lift pins 36 support the glass substrate 34 which is transferred by the robot arm 35 and positioned on the susceptor 30. At least two lift pins 36 are utilized for engaging or penetrating a side of the susceptor 30.

The robot arm 35 transfers the glass substrate 34 to the process chamber 32 often the glass substrate 34 has been pre-heated in a heating chamber (not shown). After moving to the position of the process chamber 32, the robot arm 35 moves forward in an advance direction and places the glass substrate 34 on top of the susceptor 30. The lift pins 36 supporting the glass substrate 34 are inserted into the inside of the susceptor 30 whereby the glass substrate 34 is positioned on the surface of the susceptor 30.

The robot arm 35 positions the glass substrate 34 at a location 2˜3 mm before the stopper pin 40 from the end of the glass substrate 34 when safely placing the glass substrate 34 on the surface of the susceptor 30.

At this time, to make the transfer stable upon the transfer and the conveyance of the robot arm 35, a slide part of the susceptor 30, that is, the gap between the part where the glass substrate 34 is safely positioned, and the stopper pin 40, is increased to be 10 mm. Thus, the transfer by the robot arm 35 becomes stabilized.

Also, because the glass substrate 34 is placed on the surface of the susceptor 30 with an angle of 85 degree for being safely placed, the glass substrate 34 is safely placed on the susceptor 30 inclined to one side. As a result, the friction between the surface of the susceptor 30 and the glass substrate 34 changes causing the film-forming material to collect at the slide part 42 of the susceptor 30.

To minimize the occurrence of a side miss of the glass substrate 34 due to the film-forming material, a groove 44 is formed at the slide part 42 of the susceptor 30 as shown in FIGS. 6 to 9.

FIG. 6 is a sectional view taken along the line B-B′ illustrated in FIG. 5, showing a groove formed in the slide part 42 which, in this case, has a square sectional configuration.

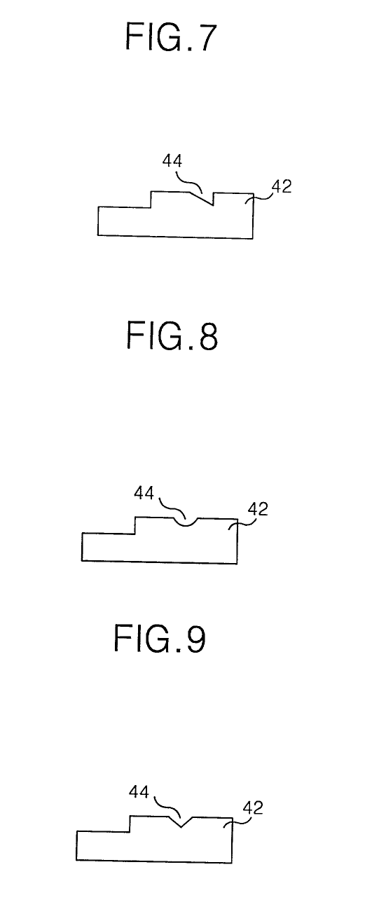

FIGS. 7 to 9 represent various shapes of the groove 44 formed at the slide part 42. The groove 44 of FIG. 7 has the shape wherein the bottom surface includes an incline plane and a perpendicular plane; The groove 44 of FIG. 8 has the shape whereby the bottom surface is a curved surface; The groove 44 of FIG. 9 has a ‘V’ shape. Also, the groove 44 formed at the slide part 42 of the susceptor 30 may have a polygonal shape (not shown), as the shape of its section.

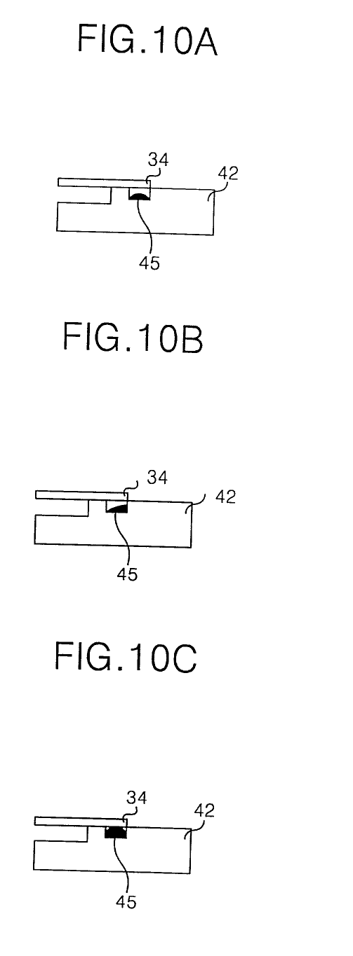

The groove 44 formed at the slide part of the susceptor 30 makes the contact surface with the film forming material 45 minimal as shown in FIG. 10a to 10c, when the glass substrate 34 is slid.

FIGS. 10a to 10c are sectional views taken along line B-B′ of FIG. 5, and represent, in steps, the occurrence of the film-forming material 45 at the groove 44, which takes place by the friction between the glass substrate 34 and the slide part 42 of the susceptor 30.

When the glass substrate 34 is slid to the slide part 42 of the susceptor 30, the film-forming material 45 which accumulates by the friction difference between the glass substrate 34 and the susceptor 30 collects in the inside of the groove 44 so that the film-forming material 45 does not contact the glass substrate 34.

In this way, when the glass substrate 34 is slid to the susceptor 30, the film-forming material 45 occurs inside of the groove 44. Thereby, the breakage of the glass substrate 34 is prevented.

The conventional susceptor 10 uses pyrex, which is a kind of glass. On the contrary, the susceptor 30 according to the present invention uses quartz as its material, to make it easy to supply the material.

As described above, with the vacuum deposition apparatus according to the present invention, the gap is increased between the part where the glass substrate 34 is safely positioned and the stopper pin 40, to make the transfer stable; the groove is formed at the slide part of the susceptor, to reduce the breakage of the glass substrate due to the film-forming material and to improve the productivity and the rate of operation. Moreover, the period between periodic cleanings of the susceptor is increased to reduce the cleaning cost, and the exchange cycle is increase to decrease the production cost.

It should be understood to the ordinary skilled person in the art that the invention is not limited to the embodiments, but rather that various changes or modifications thereof are possible without departing from the spirit of the invention. Accordingly, the scope of the invention shall be determined only by the appended claims and their equivalents.

What is claimed is:

1. A vacuum deposition apparatus comprising:
a susceptor for applying heat to a glass substrate for generating plasma;
a lift pin for supporting said glass substrate on the susceptor;
a robot arm for transferring the glass substrate to and returning the glass substrate from the susceptor;
a stopper pin facilitating the stable transfer and return of said robot arm; and
a groove formed in a slide part of the susceptor and into which a film-forming material collects upon the deposition process.

2. The vacuum deposition apparatus according to claim 1, wherein the gap between said slide part and said stopper pin is at least 3 mm.

3. The vacuum deposition apparatus according to claim 2, wherein the gap is 10 mm.

4. The vacuum deposition apparatus according to claim 1, wherein the susceptor is made of a quartz material.

5. The vacuum deposition apparatus according to claim 1, wherein the section of said groove formed in the slide part has a polygonal configuration.

6. The vacuum deposition apparatus according to claim 1, wherein the bottom face of the groove formed in the slide part has a curved configuration.

7. The vacuum deposition apparatus according to claim 1, wherein the bottom face of the groove formed in the slide part includes an incline plane and a perpendicular plane.

8. The vacuum deposition apparatus according to claim 1, wherein the groove formed in the slide part has a V-shaped configuration.
